(19) United States
(12) Patent Application Publication
(10) Pub. No.: US 2026/0121629 A1
(43) Pub. Date: Apr. 30, 2026

(54) SEMICONDUCTOR DEVICE AND ELECTRONIC CONTROL SYSTEM

(71) Applicant: Renesas Electronics Corporation, Tokyo (JP)

(72) Inventor: Akihiro NAKAHARA, Tokyo (JP)

(73) Assignee: Renesas Electronics Corporation, Tokyo (JP)

(21) Appl. No.: 19/370,032

(22) Filed: Oct. 27, 2025

(30) Foreign Application Priority Data
Oct. 29, 2024 (JP) 2024-189839

(51) Int. Cl. H03K 17/081

(52) U.S. Cl. CPC H03K 17/08104

(57) ABSTRACT

A detection transistor is configured to be turned on when a counter electromotive voltage is generated at a power output terminal and then a source voltage changes in conjunction with the counter electromotive voltage. A clamp element configured to limit a gate voltage of the detection transistor to a predetermined clamp voltage with reference to the voltage of the power output terminal. A gate connection circuit comprises a resistance element configured to connect the power output terminal to the gate of the detection transistor, and an nMOS transistor configured to apply a ground power supply voltage to the gate of the detection transistor and cut off a current in a direction from the gate of the detection transistor toward the ground power supply voltage.

### CROSS-REFERENCE TO RELATED APPLICATION

This application claims priority under 35 U.S.C. §119 to Japanese Patent Application No. 2024-189839 filed on October 29, 2024. The disclosure of Japanese Patent Application No. 2024-189839, including the specification, drawings and abstract is incorporated herein by reference in its entirety.

### BACKGROUND

The present invention relates to a semiconductor device and an electronic control system, and for example, relates to a semiconductor device that supplies power to a load connected to the outside, and an electronic control system on which the semiconductor device is mounted.

There are disclosed techniques listed below.

Patent Document 1 Japanese Unexamined Patent Application Publication No. 2023-47804

Patent Document 2 Japanese Unexamined Patent Application Publication No. 2007-28747

Patent Document 1 discloses a semiconductor device capable of preventing destruction of an output transistor due to secondary breakdown. The semiconductor device includes a detection transistor, a control transistor, and an output transistor. The detection transistor causes a detection current to flow during a period when an output voltage generated at the load terminal is lower than a ground voltage. The control transistor is controlled to be on during a period when the detection current flows. The output transistor is controlled to be off during a period when the control transistor is controlled to be on, that is, during a period when the output voltage is lower than the ground voltage.

Patent Document 2 discloses an overvoltage protection circuit capable of preventing a circuit malfunction caused by a set value of a dynamic clamp voltage. The overvoltage protection circuit includes an output transistor, a load, a dynamic clamp circuit, and a clamp switch. The output transistor is connected between a power supply and an output terminal. The load is connected to the output terminal. The dynamic clamp circuit limits the voltage difference between the power supply and the output terminal. The clamp switch is connected between the dynamic clamp circuit and the output terminal, and the conduction state is determined based on a comparison result between a reference voltage and a voltage of the output terminal.

### SUMMARY

For example, as disclosed in Patent Document 1 and Patent Document 2, a configuration in which power is supplied from the output transistor to the load via the output terminal is known. For example, if the load is inductive, a counter electromotive voltage, e.g., a negative voltage, may be generated at the output terminal when the output transistor is turned off. Even when the load is not inductive, the counter electromotive voltage may be generated at the output terminal, for example, due to a parasitic inductance component of the wire harness. With the configuration disclosed in Patent Document 1, such a negative voltage can be clamped by a body diode of the output transistor fixed to be off. In addition, when the configuration disclosed in Patent Document 2 is used, such a negative voltage can be clamped by the dynamic clamp circuit.

However, in the configurations disclosed Patent Document 1 and Patent Document 2, a high voltage can be applied to the detection transistor that detects the voltage of the output terminal and the clamp switch. For this reason, the detection transistor, and the clamp switch that actually is formed from a transistor, need to be constituted by, for example, a high-voltage Metal Oxide Semiconductor Field Effect Transistor (MOSFET) having a thick gate oxide film. Accordingly, an additional manufacturing process is required, and as a result, the manufacturing cost may increase.

Embodiments to be described later have been made in view of such circumstances, and other problems and novel features will be apparent from the description of the present specification and the accompanying drawings.

A semiconductor device according to an embodiment comprises an output transistor, a detection transistor, a first clamp element, and a gate connection circuit. The output transistor is connected between a first power supply terminal to which a first power supply voltage is supplied and a power output terminal, and, when controlled to be turned on, configured to supply, via the power output terminal, power to a load having one end to which a second power supply voltage is supplied. The detection transistor is inserted into a path between the first power supply terminal and the power output terminal, and is configured to be turned on when a counter electromotive voltage is generated at the power output terminal and a source voltage changes in conjunction with the counter electromotive voltage. The first clamp element configured to limit a gate voltage of the detection transistor to a predetermined clamp voltage with reference to the voltage of the power output terminal. The gate connection circuit is connected to the gate of the detection transistor. The gate connection circuit comprises a first resistance element configured to connect a power output terminal to the gate of the detection transistor, and a rectifier element configured to apply a second power supply voltage to the gate of the detection transistor and cut off a current in a direction from the gate of the detection transistor toward the second power supply voltage.

According to the above embodiment, the manufacturing cost can be reduced in the semiconductor device that supplies power to the load and the electronic control system on which the semiconductor device is mounted.

### BRIEF DESCRIPTIONS OF THE DRAWINGS

FIG. 1 is a circuit diagram illustrating a configuration example of a main part of a semiconductor device according to a first embodiment.

FIG. 2 is a timing chart illustrating an operation example of the semiconductor device in FIG. 1.

FIG. 3 is a graph illustrating an example of current-voltage characteristics of a zener diode, which is one of clamp elements in FIG. 1.

FIG. 4 is a graph illustrating an example of a detailed power supply voltage waveform associated with a load dump in FIG. 2.

FIG. 5 is a cross-sectional view illustrating an example of a device structure in the semiconductor device illustrated in FIG. 1.

FIG. 6 is a circuit block diagram illustrating a configuration example of an electronic control system (ECU) to which the semiconductor device illustrated in FIG. 1 is applied.

FIG. 7 is a schematic diagram illustrating a configuration example of a vehicle on which an electronic control system (ECU) illustrated in FIG. 6 is mounted.

FIG. 8 is a circuit diagram illustrating a configuration example of a main part of a semiconductor device according to a second embodiment.

FIG. 9 is a circuit diagram illustrating a configuration example of a main part of a semiconductor device according to a third embodiment.

FIG. 10 is a timing chart illustrating an operation example of the semiconductor device in FIG. 9.

FIG. 11 is a circuit diagram illustrating a configuration example of the semiconductor device according to the third embodiment, obtained by modifying FIG. 9.

FIG. 12 is a circuit diagram illustrating a configuration example of a main part of a semiconductor device according to a fourth embodiment.

FIG. 13 is a timing chart illustrating an operation example of the semiconductor device in FIG. 12.

FIG. 14 is a circuit diagram illustrating a configuration example of a main part of a semiconductor device that is a first comparative example with reference to FIG. 1.

FIG. 15 is a cross-sectional view illustrating an example of a device structure in the semiconductor device illustrated in FIG. 14.

FIG. 16 is a circuit diagram illustrating a configuration example of a main part of a semiconductor device that is a second comparative example with reference to FIG. 9.

### DETAILED DESCRIPTION

In the following embodiments, when necessary for the sake of convenience, the description will be divided into a plurality of sections or embodiments, but unless otherwise specified, the sections or embodiments are not unrelated to each other, and one is in a relationship of some or all modifications, details, supplementary explanation, and the like with the other. In addition, in the following embodiments, when the number of elements or the like (including number of pieces, numerical value, amount, range, and the like) is mentioned, the number is not limited to a specific number unless otherwise specified or obviously limited to the specific number in principle, and the number may be equal to or more than the specific number or may be equal to or less than the specific number.

Furthermore, in the following embodiments, it goes without saying that the components (including element steps or the like) are not necessarily essential unless otherwise specified or considered to be obviously essential in principle. Similarly, in the following embodiments, when the shape, positional relationship, or the like of the components or the like is mentioned, those substantially approximate or similar to the shape or the like are included unless otherwise specified or considered obviously otherwise in principle. The same applies to the above-described numerical value and range.

In addition, in the following embodiments, a p-channel MOSFET and an n-channel MOSFET are referred to as a pMOS transistor and an nMOS transistor, respectively. Hereinafter, the embodiments of the present invention will be described in detail with reference to the drawings. In all the drawings for describing the embodiments, the same members are denoted by the same reference numerals in principle, and repeated description thereof will be omitted.

### First Embodiment

### Circuit Configuration of Semiconductor Device

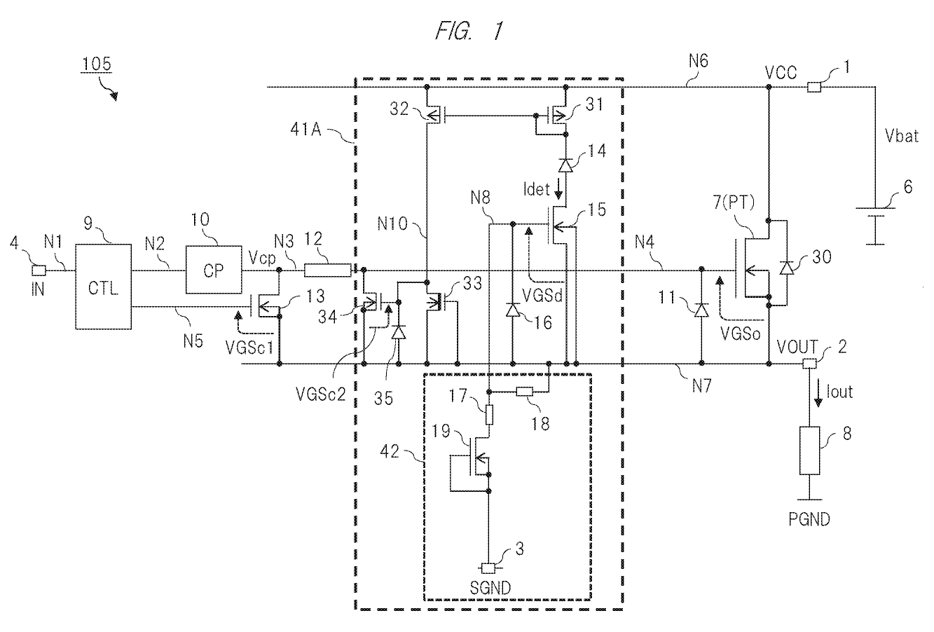

FIG. 1 is a circuit diagram illustrating a configuration example of a main part of a semiconductor device 105 according to a first embodiment. The semiconductor device 105 illustrated in FIG. 1 includes a power supply terminal 1, a power output terminal 2, a ground power supply terminal 3, a control input terminal 4, a power transistor (PT) 7, and various control circuits that control the power transistor (PT) 7. The various control circuits include an on/off control circuit (CTL) 9, a charge pump circuit (CP) 10, a clamp element 11, a gate resistance element 12, a control switch 13, and a protection circuit 41A. Details of the protection circuit 41A will be described later.

The power supply terminal 1 receives a battery voltage Vbat, for example 12 V, from an external battery 6 via power supply wiring. As a result, a power supply voltage (first power supply voltage) VCC is supplied to the power supply terminal 1, that is, a power supply node N6. The power output terminal 2 is connected to a load 8. The load 8 is, for example, an inductive load. The load 8 has one end to which a ground power supply voltage (second power supply voltage) PGND is supplied. In addition, an output voltage VOUT and an output current IOUT are generated at the power output terminal 2.

The power transistor (PT) 7 is also an output transistor connected between the power supply terminal 1 and the power output terminal 2. When controlled to be turned on, the power transistor (PT) 7 supplies power to the load 8 connected to the power output terminal 2 via the power output terminal 2. In this example, the power transistor (PT) 7 is an nMOS transistor. The source and the drain of the power transistor (PT) 7 are connected to the power output terminal 2 and the power supply terminal 1, respectively.

The power transistor (PT) 7 includes a body diode 30 having the commonly connected source and back gate as an anode and the drain as a cathode. The clamp element 11, specifically a zener diode, clamps a gate-source voltage VGSo of the power transistor (PT) 7. As a result, a gate voltage of the power transistor (PT) 7 is limited so as not to be excessively increased by a charge pump circuit 10.

The control input terminal 4 receives an on/off control signal IN from the outside. The on/off control circuit 9 exclusively controls the charge pump circuit 10 and the control switch 13 in response to the on/off control signal IN. The control switch 13 is, for example, an nMOS transistor. When controlled to be turned on, the control switch 13 short-circuits an output node N3 of the charge pump circuit 10 and the power output terminal 2, that is, a power output node N7.

For example, when the on/off control signal IN is an on-level, the on/off control circuit 9 activates the charge pump circuit 10. As a result, the charge pump circuit 10 generates a boosted voltage Vcp higher than the power supply voltage VCC. The boosted voltage Vcp is applied to a gate node N4 of the power transistor (PT) 7 via the gate resistance element 12. On the other hand, when the on/off control signal IN is an off-level, the on/off control circuit 9 controls the control switch 13 to be turned on. As a result, the gate and the source are short-circuited via the gate resistance element 12 and the control switch 13, thereby causing the power transistor (PT) 7 to be controlled to be turned off.

Here, an operation in a case where the protection circuit 41A is not provided will be described. When the on/off control signal IN transitions from the on-level to the off-level, the power transistor (PT) 7 is turned off. At this time, a counter electromotive voltage, here, a negative voltage lower than the ground power supply voltage PGND of 0 V is generated at the power output terminal 2 due to the action of the load 8, for example. On the other hand, since the gate and the source are short-circuited via the gate resistance element 12 and the control switch 13, the power transistor (PT) 7 is maintained to be off.

As a result, the power transistor (PT) 7 can clamp the drain-source voltage, and thus the counter electromotive voltage generated at the power output terminal 2, based on the clamp voltage of the body diode 30, in other words, a zener voltage. In addition, the power transistor (PT) 7 can consume flyback energy associated with the counter electromotive voltage via the body diode 30. Such a clamping operation is called an avalanche clamping operation or the like.

However, a problem may occur in a case where the on/off control signal IN transitions from the off-level to the on-level during a period when the counter electromotive voltage is generated at the power output terminal 2. In this case, as a result of the turn-off of the control switch 13 and the activation of the charge pump circuit 10, the power transistor (PT) 7 is turned on in a state where a high drain-source voltage is applied. As a result, the power transistor (PT) 7 may deviate from a safe operation area (SOA) and be destroyed. Therefore, the protection circuit 41A is provided so as to maintain the off-state of the power transistor (PT) 7 even in such a case.

### Protection Circuit as Comparative Example

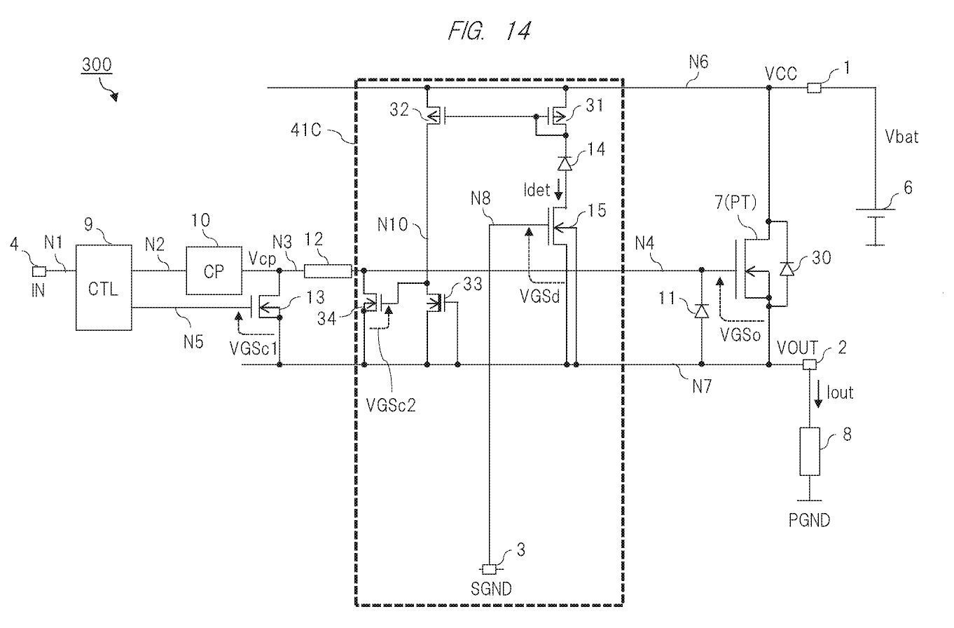

Here, prior to description of the protection circuit 41A, a protection circuit serving as a first comparative example will be described. FIG. 14 is a circuit diagram illustrating a configuration example of a main part of a semiconductor device 300 that is the first comparative example with reference to FIG. 1. The semiconductor device 300 illustrated in FIG. 14 has a protection circuit 41C that has a different configuration from that of the protection circuit of the semiconductor device 105 illustrated in FIG. 1. The protection circuit 41C illustrated in FIG. 14 includes a detection transistor 15, a zener diode 14, pMOS transistors 31 and 32, an nMOS transistor 33, and a control switch 34.

The detection transistor 15 is inserted into a path between the power supply terminal (first power supply terminal) 1 and the power output terminal 2. The detection transistor 15 is roughly configured to be turned on when the counter electromotive voltage is generated at the power output terminal 2 and then a source voltage changes in conjunction with the counter electromotive voltage.

Specifically, the detection transistor 15 is constituted by, for example, an nMOS transistor. The source and the back gate of the detection transistor 15 are connected to the power output terminal 2. The gate of the detection transistor 15 is connected to the ground power supply terminal 3. A ground power supply voltage (second power supply voltage) SGND that is 0 V is applied to the ground power supply terminal 3. As a result, the detection transistor 15 is turned on when a negative voltage is generated at the power output terminal 2, specifically, when a gate-source voltage VGSd equal to or higher than a threshold voltage is generated due to the negative voltage. When turned on, the detection transistor 15 causes a detection current Idet to flow.

The zener diode 14 is inserted into a path between the power supply terminal 1, that is, the power supply node N6 and the drain of the detection transistor 15. The zener diode 14 determines an upper limit value of the output voltage VOUT necessary for enabling the protection circuit 41C. That is, when the output voltage VOUT drops so as to exceed the zener voltage of the zener diode 14 with reference to the power supply voltage VCC, the protection circuit 41C is brought into the enabled state. As a result, for example, when a negative voltage at a noise level that is not the counter electromotive voltage is generated, the protection circuit 41C can be maintained in a disabled state, thus preventing the protection circuit 41C from being unnecessarily enabled.

As a specific example, the clamp voltage of the body diode 30 is 40 V or the like. On the other hand, the zener voltage of the zener diode 14 is set to 18 V or the like. In a case where the power supply voltage VCC is 12 V, the protection circuit 41C is brought into the enabled state when the output voltage VOUT drops below -6 V. In addition, at the point when the detection transistor 15 is brought into the enabled state, the detection transistor 15 is in the on-state since the gate-source voltage VGSd of 6 V is applied. Note that the protection circuit 41C needs to be enabled at least before the avalanche clamping operation by the body diode 30 starts. Therefore, the zener voltage of the zener diode 14 is determined to be lower than the clamp voltage of the body diode 30.

The pMOS transistors 31 and 32 constitute a current mirror circuit. The pMOS transistor 31 serving as the copy source copies the detection current Idet flowing through the detection transistor 15 to the pMOS transistor 32 serving as the copy destination. The nMOS transistor 33 is connected between a node N10 serving as the drain of the pMOS transistor 32 and the power output node N7. The nMOS transistor 33 is, for example, a depletion-type transistor whose gate and source are short-circuited, and functions as a current source or a high resistance element. The nMOS transistor 33 is also a voltage conversion element that converts the current copied to the node N10 into a voltage.

The control switch (first control switch) 34 is controlled to be turned on/off by the voltage converted by the nMOS transistor 33. When controlled to be turned on, that is, when the detection current Idet flows through the detection transistor 15 in response to the negative voltage, the control switch 34 short-circuits the gate and the source of the power transistor (PT) 7. The control switch 34 is constituted by an nMOS transistor whose source and drain are connected to the power output node N7 and the gate node N4, respectively.

By providing such a protection circuit 41C, as described above, even when the on/off control signal IN transitions from the off-level to the on-level during the period when the counter electromotive voltage is generated at the power output terminal 2, the control switch 34 can be maintained in the on-state as long as the counter electromotive voltage is generated. As a result, since the power transistor (PT) 7 can be maintained in the off-state, the power transistor (PT) 7 can be prevented from being destroyed.

However, in the configuration example illustrated in FIG. 14, a high gate-source voltage VGSd can be applied particularly in the detection transistor 15. For example, in a case where the power supply voltage VCC is 12 V and the clamp voltage of the body diode 30 is 40 V, the output voltage VOUT is -28 V during a period when the avalanche clamping operation is performed. In this case, the gate-source voltage VGSd is +28 V. Therefore, the detection transistor 15 needs to be constituted by a high-voltage MOS transistor.

### Device Structure as Comparative Example

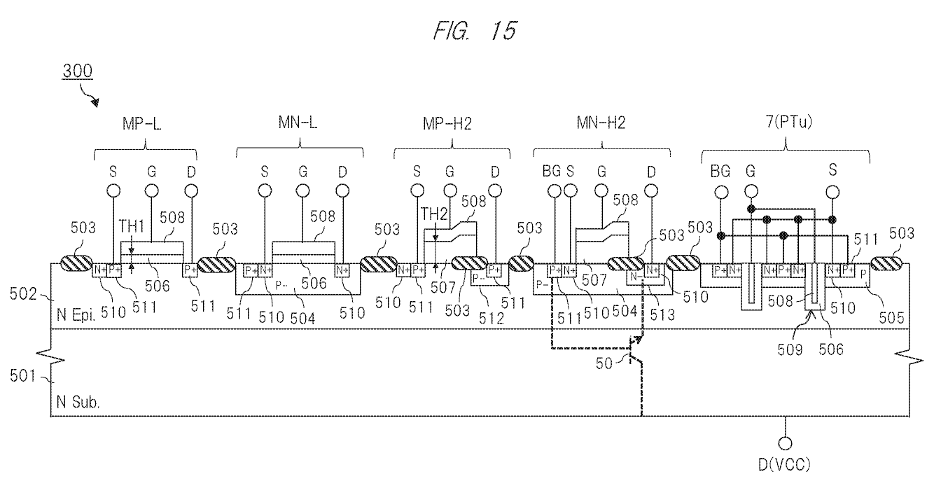

FIG. 15 is a cross-sectional view illustrating an example of a device structure in the semiconductor device 300 illustrated in FIG. 14. FIG. 15 illustrates a unit output transistor PTu, a pMOS transistor MP-L and an nMOS transistor MN-L of low-voltage specification, and a pMOS transistor MP-H2 and an nMOS transistor MN-H2 of high-withstand-voltage specification. Specifically, the power transistor (PT) 7 is constituted by a plurality of unit output transistors PTu connected in parallel to each other. One unit output transistor PTu of the plurality of unit output transistors PTu is illustrated in FIG. 15. In addition, the various control circuits described in FIG. 1 are constituted using the pMOS transistors MP-L and MP-H2 and the nMOS transistors MN-L and MN-H2.

In FIG. 15, an N-type epitaxial layer 502 is formed on an N-type semiconductor substrate 501. The unit output transistor PTu, the pMOS transistors MP-L and MP-H2, and the nMOS transistors MN-L and MN-H2 are formed using a diffusion layer or the like disposed on a surface of the epitaxial layer 502. In addition, the unit output transistor PTu, the pMOS transistors MP-L and MP-H2, and the nMOS transistors MN-L and MN-H2 are separated from each other by a thick oxide film 503 (LOCOS).

The unit output transistor PTu is constituted by a vertical nMOS transistor having the back surface of the semiconductor substrate 501 as the drain. Specifically, a Pbase diffusion layer 505 serving as a back gate (BG) is formed on the surface of the epitaxial layer 502. In the Pbase diffusion layer 505, an N⁺-type source (S) diffusion layer 510 and a P⁺-type power supply diffusion layer 511 for supplying power to the back gate (BG) are formed. The epitaxial layer 502 and the semiconductor substrate 501 serve as a drain (D). The power supply voltage VCC is supplied to the drain (D), that is, the back surface of the semiconductor substrate 501.

A trench 509 extending in the depth direction is formed in the epitaxial layer 502. A thin gate oxide film 506 and polysilicon 508 serving as a gate (G) are embedded in the trench 509. The source (S) diffusion layer 510 is formed at a position in contact with the sidewall of the trench 509. When a predetermined voltage is applied between the gate (G) and the source (S), a channel is formed at a position located on the sidewall of the trench 509 in the Pbase diffusion layer 505. As a result, a drive current flows from the back surface of the semiconductor substrate 501 toward the source (S) diffusion layer 510.

In the pMOS transistor MP-L of the low-voltage specification, the P⁺-type source (S) diffusion layer 511 and the drain (D) diffusion layer 511, and the N⁺-type power supply diffusion layer 510 for the back gate are formed on the surface of the epitaxial layer 502. On the epitaxial layer 502 located between the source (S) diffusion layer 511 and the drain (D) diffusion layer 511, the polysilicon 508 serving as the gate (G) is formed via the thin gate oxide film 506.

In the nMOS transistor MN-L of the low-voltage specification, a P⁻-type deep diffusion layer 504, that is, a p-well is formed from the surface of the epitaxial layer 502. In the P⁻-type diffusion layer 504, the N⁺-type source (S) diffusion layer 510 and the drain (D) diffusion layer 510, and the P⁺-type power supply diffusion layer 511 for the back gate are formed. On the epitaxial layer 502 located between the source (S) diffusion layer 510 and the drain (D) diffusion layer 510, the polysilicon 508 serving as the gate (G) is formed via the thin gate oxide film 506. Note that the pMOS transistor MP-L and the nMOS transistor MN-L of the low-voltage specification have a withstand voltage of about 6 V, for example.

In the pMOS transistor MP-H2 of the high-voltage specification, the P⁺-type source (S) diffusion layer 511 and the N⁺-type power supply diffusion layer 510 for the back gate are formed on the surface of the epitaxial layer 502. On the other hand, on the drain (D) side, a P⁻-type deep diffusion layer 512 is formed from the surface of the epitaxial layer 502. The P⁺-type drain (D) diffusion layer 511 is formed in the P⁻-type diffusion layer 512.

On the epitaxial layer 502 located between the source (S) diffusion layer 511 and the drain (D) diffusion layer 511, the polysilicon 508 serving as the gate (G) is formed via a thick gate oxide film 507. In this manner, a film thickness TH2 of the gate oxide film 507 used in the high-voltage specification is larger than a film thickness TH1 of the gate oxide film 506 used in the low-voltage specification. Furthermore, unlike the case of the low-voltage specification, the gate oxide film 507 and the polysilicon 508 in the vicinity of the drain (D) ride on the thick oxide film 503 to realize a high withstand voltage.

In the nMOS transistor MN-H2 of the high-voltage specification, a P⁻-type deep diffusion layer 504, that is, a p-well is formed from the surface of the epitaxial layer 502. In the P⁻-type diffusion layer 504, the N⁺-type source (S) diffusion layer 510 and the P⁺-type power supply diffusion layer 511 for the back gate are formed. On the other hand, on the drain (D) side, an N⁻-type deep diffusion layer 513 is formed from the surface of the epitaxial layer 502. The N⁺-type drain (D) diffusion layer 510 is formed in the N⁻-type diffusion layer 513.

On the epitaxial layer 502 located between the source (S) diffusion layer 510 and the drain (D) diffusion layer 510, the polysilicon 508 serving as the gate (G) is formed via the thick gate oxide film 507. As in the case of the pMOS transistor MP-H2, the film thickness TH2 of the gate oxide film 507 is larger than the film thickness TH1 used in the low-voltage specification. In addition, the gate oxide film 507 and the polysilicon 508 in the vicinity of the drain (D) ride on the thick oxide film 503 to realize a high withstand voltage.

Note that an NPN parasitic bipolar transistor 50 can be formed in the nMOS transistor MN-H2 as illustrated in FIG. 15. The parasitic bipolar transistor 50 operates using the N⁺-type drain (D) diffusion layer 510 and the N⁻-type deep diffusion layer 513 as emitters, the P⁺-type power supply diffusion layer 511 and the P⁻-type deep diffusion layer 504 as bases, and the N-type semiconductor substrate 501 and the epitaxial layer 502 as collectors. Although not illustrated, the parasitic bipolar transistor can also be formed in the nMOS transistor MN-L.

In the device structure as described above, the detection transistor 15 needs to be constituted by, for example, the nMOS transistor MN-H2 of the high-voltage specification. In addition, most of the other transistors can be constituted by the pMOS transistor MP-L and the nMOS transistor MN-L of the low-voltage specification. Thus, in the manufacturing process, a step of forming the gate oxide film 506 having the thin film thickness TH1 and a step of forming the gate oxide film 507 having the thick film thickness TH2 are individually required. As a result, the manufacturing cost may increase.

### Protection Circuit According to Embodiment

Therefore, the protection circuit 41A illustrated in FIG. 1 is provided. The protection circuit 41A includes a clamp element 16, a gate connection circuit 42, and a clamp element 35 in addition to the same components as those of the protection circuit 41C illustrated in FIG. 14. The clamp element (first clamp element) 16, specifically the zener diode, limits the gate voltage of the detection transistor 15 to a predetermined clamp voltage with reference to the output voltage VOUT. That is, the clamp element 16 clamps the gate-source voltage VGSd and a gate-back gate voltage of the detection transistor 15.

The clamp element (second clamp element) 35, specifically the zener diode, limits a gate-source voltage VGSc2 of the control switch (first control switch) 34 to a predetermined clamp voltage. That is, when a counter electromotive voltage is generated at the power output terminal 2, a high voltage may be generated not only in the detection transistor 15 but also between the gate and the source of the control switch 34. Therefore, the clamp element 35 is provided. Note that the clamp voltage of the clamp elements 16 and 35, that is, the zener voltage is, for example, 6 V or the like.

The gate connection circuit 42 is connected to the gate of the detection transistor 15. The gate connection circuit 42 includes two resistance elements 17 and 18 and an nMOS transistor 19 that is a rectifier element. The resistance element (first resistance element) 18 connects the power output terminal 2 to the gate of the detection transistor 15. The nMOS transistor 19 applies the ground power supply voltage (second power supply voltage) SGND to the gate of the detection transistor 15, and cuts off a current in a direction from the gate of the detection transistor 15 toward the ground power supply voltage SGND.

In this example, the gate and the source of the nMOS transistor 19 are short-circuited. In addition, the source and the back gate of the nMOS transistor 19 are commonly connected. As a result, the nMOS transistor 19 functions as a diode having the source and the back gate as an anode and the drain as a cathode.

Specifically, the nMOS transistor 19 is a diode element using a body diode between the back gate and the drain, and is also a transistor diode-connected such that the source is replaced with the drain. The nMOS transistor 19 functioning as the diode applies the ground power supply voltage SGND that has been input to the anode, from the cathode to the gate of the detection transistor 15. In addition, the nMOS transistor 19 functioning as the diode cuts off a current in a direction from the cathode to the anode.

The resistance element (second resistance element) 17 is connected in series to the nMOS transistor 19. Specifically, the resistance element 17 is connected between the drain of the nMOS transistor 19 and a node N8 that is the gate of the detection transistor 15. Although described in detail later, the resistance element 17 is provided to limit a current flowing from the ground power supply voltage SGND to the clamp element 16 via the gate of the detection transistor 15.

In the above configuration, first, the clamp element 16 is provided, so that the upper limits of the gate-source voltage VGSd and the gate-back gate voltage of the detection transistor 15 can be limited to 6 V or the like. As a result, the detection transistor 15 can be constituted by an nMOS transistor having a thin gate oxide film. However, for example, simply adding the clamp element 16 to the configuration example illustrated in FIG. 14 may cause a problem not in the avalanche clamping operation but in the normal operation.

That is, in the normal operation, when the power transistor (PT) 7 is controlled to be turned on, a through current flows from the power output terminal 2 to which the substantial power supply voltage VCC is applied, to the ground power supply terminal 3 to which the ground power supply voltage SGND is applied, via the forward clamp element 16. To respond to this, in FIG. 1, the nMOS transistor 19 functioning as the diode is provided. This makes it possible to prevent such a through current. Note that a normal diode element may be provided instead of the nMOS transistor 19.

On the other hand, the nMOS transistor 19 functioning as the diode is reverse-biased during a period when a negative voltage is not generated at the power output terminal 2. During this period, the node N8 that is the gate of the detection transistor 15 can hold a voltage higher than the ground power supply voltage SGND, for example, the substantial power supply voltage VCC or the like via the forward clamp element 16. As a result, the detection transistor 15 can be turned on even during the period when a negative voltage is not generated at the power output terminal 2, for example, the period when the power transistor (PT) 7 is in the on-state.

Therefore, in FIG. 1, the resistance element 18 that connects the power output terminal 2 and the node N8 is provided. This makes it possible to short-circuit the power output terminal 2 and the node N8 during the period when a negative voltage is not generated at the power output terminal 2, that is, during the period when the nMOS transistor 19 functioning as the diode is reverse-biased. As a result, the detection transistor 15 can be maintained to be off.

### Operation of Semiconductor Device

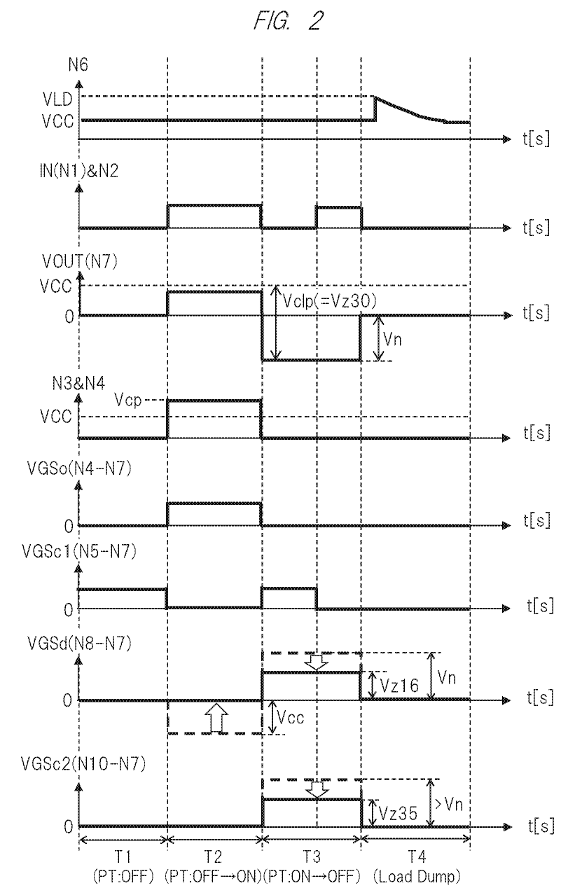

FIG. 2 is a timing chart illustrating an operation example of the semiconductor device 105 in FIG. 1. In FIG. 2, the gate-source voltages VGSd and VGSc2 when the configuration example illustrated in FIG. 14 is used are also illustrated for comparison. In addition, FIG. 2 illustrates four periods T1 to T4. The period T1 is a period during which the power transistor (PT) 7 is in the off-state. The period T2 is a period after the power transistor (PT) 7 is turned on. The period T3 is a period after the power transistor (PT) 7 is turned off. The period T4 is a period during which a load dump occurs.

### Period T1 PT: Off

The control input terminal 4 receives the on/off control signal IN at an “L” level, that is, at the off-level. In response to this, the on/off control circuit 9 controls the control switch 13 to be turned on by outputting an “H” level to a node N5, that is, a gate-source voltage VGSc1. In addition, the on/off control circuit 9 controls the charge pump circuit 10 to be in an inactive state by outputting the “L” level to a node N2. The power transistor (PT) 7 is brought into the off-state when the gate-source voltage VGSo becomes 0 V in response to the control switch 13 being turned on.

On the other hand, the output voltage VOUT generated at the power output node N7 becomes the ground power supply voltage PGND in response to the power transistor (PT) 7 being turned off. At this time, the gate voltage of the detection transistor 15, that is, the voltage of the node N8 becomes equal to the voltage of the power output node N7 via the resistance element 18. As a result, the detection transistor 15 is brought into the off-state when the gate-source voltage VGSd becomes 0 V.

### Period T2 PT: Turn-on and On

The control input terminal 4 receives the on/off control signal IN at the “H” level, that is, at the on-level. In response to this, the on/off control circuit 9 controls the control switch 13 to be turned off by outputting the “L” level to the node N5, that is, the gate-source voltage VGSc1. In addition, the on/off control circuit 9 controls the charge pump circuit 10 to be in an active state by outputting the “H” level to the node N2. As a result, the boosted voltage Vcp is applied to the gate node N4 of the power transistor (PT) 7. The power transistor (PT) 7 is turned on when the gate-source voltage VGSo at the on-level is applied.

The output voltage VOUT becomes substantially the same level as the power supply voltage VCC through the power transistor (PT) 7 in the on-state. At this time, the gate voltage of the detection transistor 15, that is, the voltage of the node N8 becomes equal to the voltage of the power output node N7 via the resistance element 18. As a result, the detection transistor 15 is brought into the off-state when the gate-source voltage VGSd becomes 0 V. On the other hand, when the configuration example illustrated in FIG. 14 is used, the gate-source voltage VGSd becomes an off-voltage having the same magnitude as the output voltage VOUT, that is, the power supply voltage VCC.

In addition, as illustrated in FIG. 1, when the nMOS transistor 19 functioning as the diode is provided, no particular problem occurs even if the output voltage VOUT becomes substantially the same level as the power supply voltage VCC in this manner. That is, the current in the direction from the power output terminal 2 toward the ground power supply terminal 3 via the clamp element 16 or the resistance elements 18 and 17 can be cut off by the nMOS transistor 19 functioning as the diode.

### Period T3 PT: Turn-off and Off

The control input terminal 4 receives the on/off control signal IN at an “L” level again. In response to this, as in the case of the period T1, the control switch 13 is turned on, and the charge pump circuit 10 is brought into the inactive state, causing the power transistor (PT) 7 to be turned off. At this time, the flyback energy accumulated in the load 8 is released. Due to the counter electromotive voltage at this time, the output voltage VOUT becomes a negative voltage. As a result, the avalanche clamping operation is performed.

The output voltage VOUT is clamped so as not to drop below a predetermined negative voltage Vn based on a clamp voltage Vclp of the body diode 30 of the power transistor (PT) 7, that is, a zener voltage Vz30. The avalanche clamping operation is maintained as long as the power transistor (PT) 7 is in the off-state. In the avalanche clamping operation, the flyback energy is released through the body diode 30. Then, when the flyback energy is completely released, the output voltage VOUT becomes the ground power supply voltage PGND.

However, as illustrated in FIG. 2, when the on/off control signal IN becomes the “H” level during the period of the avalanche clamping operation, the control switch 13 is turned off, and the charge pump circuit 10 is brought into the active state. As a result, if the power transistor (PT) 7 is turned on, the avalanche clamping operation cannot be maintained. Furthermore, since the power transistor (PT) 7 is turned on when a high drain-source voltage is applied, the power transistor (PT) 7 has an operating point outside the safe operation area (SOA). In this case, the power transistor (PT) 7 may be destroyed due to thermal runaway.

On the other hand, when the protection circuit 41A is provided, the avalanche clamping operation, that is, the off-state of the power transistor (PT) 7 can be maintained even in such a case. Specifically, first, when the output voltage VOUT becomes a negative voltage, a current flows from the ground power supply terminal 3 via the power output node N7 and the load 8. As a result, the gate voltage of the detection transistor 15, that is, the voltage of the node N8 becomes a voltage obtained when the ground power supply voltage SGND, 0 V, drops by the forward voltage of the body diode of the nMOS transistor 19, for example, 0.6 V or the like.

As a result, the detection transistor 15 is brought into the on-state since the gate-source voltage VGSd becomes the on-level. At this time, the gate-source voltage VGSd of the detection transistor 15 is limited by the clamp voltage of the clamp element 16, that is, the zener voltage Vz16 of 6 V or the like. On the other hand, when the configuration example illustrated in FIG. 14 is used, the gate-source voltage VGSd becomes an on-voltage having the magnitude of the negative voltage Vn generated at the power output node N7, for example, 28 V or the like.

When the detection transistor 15 is brought into the on-state, the node N10 serving as the copy destination of the current mirror circuit becomes the “H” level. As a result, the gate-source voltage VGSc2 of the control switch 34 becomes the on-level. At this time, the gate-source voltage VGSc2 is limited by the clamp voltage of the clamp element 35, that is, the zener voltage Vz35 of 6 V or the like. On the other hand, when the configuration example illustrated in FIG. 14 is used, the gate-source voltage VGSc2 can be an on-voltage larger than the negative voltage Vn.

The control switch 34 is turned on when the gate-source voltage VGSc2 becomes the on-level. The control switch 34 maintains the on-state as long as the detection transistor 15 is in the on-state and thus the output voltage VOUT is a negative voltage. The gate-source voltage VGSo of the power transistor (PT) 7 is 0 V as long as the control switch 34 is in the on-state. As a result, the power transistor (PT) 7 maintains the off-state and maintains the avalanche clamping operation independently of the on/off control signal IN, as long as the output voltage VOUT is a negative voltage.

Here, a current path from the ground power supply terminal 3 to the power output terminal 2 when the output voltage VOUT becomes a negative voltage includes a path via the resistance element 18 and a path via the clamp element 16. At this time, if the current flowing through the clamp element 16 increases, the clamp voltage can increase due to the operating resistance.

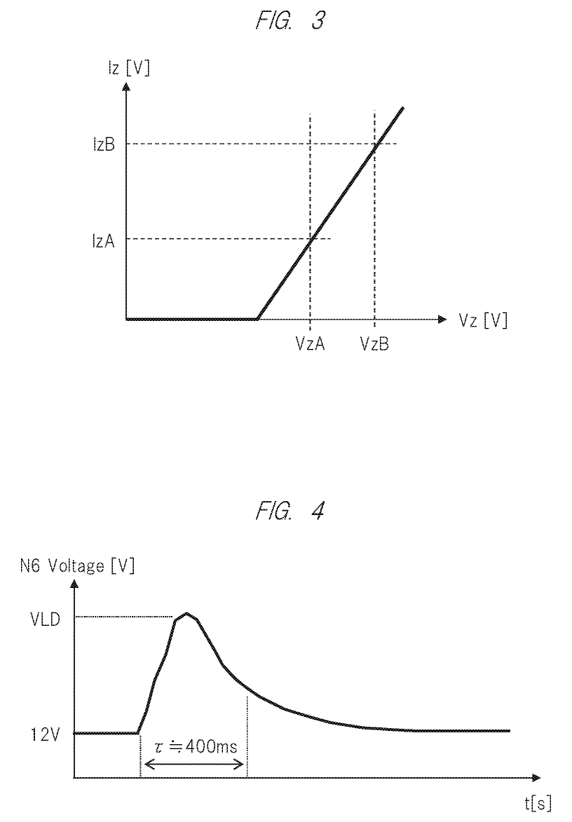

FIG. 3 is a graph illustrating an example of current-voltage characteristics of the zener diode, which is one of the clamp elements in FIG. 1. As illustrated in FIG. 3, when a zener current Iz flowing through the zener diode increases from “IzA” to “IzB”, the zener voltage Vz also increases from “VzA” to “VzB”. In this manner, when the clamp voltage of the clamp element 16 increases, the gate-source voltage VGSd of the detection transistor 15 may exceed the withstand voltage. Therefore, in FIG. 1, the resistance element 17 is provided. As a result, the zener current Iz flowing through the clamp element 16 can be limited, and fluctuation of the clamp voltage can be suppressed.

### Period T4 Load Dump

During the period T4, a period when the power transistor (PT) 7 is in the off-state, a high voltage surge occurs at the power supply terminal 1, that is, the power supply node N6. As one of power supply surges, there is a high-energy surge called a load dump. FIG. 4 is a graph illustrating an example of a detailed power supply voltage waveform associated with the load dump in FIG. 2. As illustrated in FIG. 4, the power supply voltage VCC increases from 12 V to a predetermined load dump voltage VLD due to the load dump, and returns to about 12 V through a time constant τ of about 400 ms, for example.

Also when the load dump occurs, a high voltage is applied between the drain and the source of the power transistor (PT) 7 as in the case where the counter electromotive voltage is generated. However, if the power transistor (PT) 7 also performs the avalanche clamping operation against the load dump, the power transistor (PT) 7 may be destroyed due to high energy. Therefore, a countermeasure against the load dump is taken by a circuit not illustrated in FIG. 1. In parallel with this, the detection transistor 15 needs to be maintained in the off-state against the load dump. The detection transistor 15 illustrated in FIG. 1 is configured to be capable of maintaining the off-state when a positive voltage fluctuates at the power supply node N6.

### Device Structure According to Embodiment

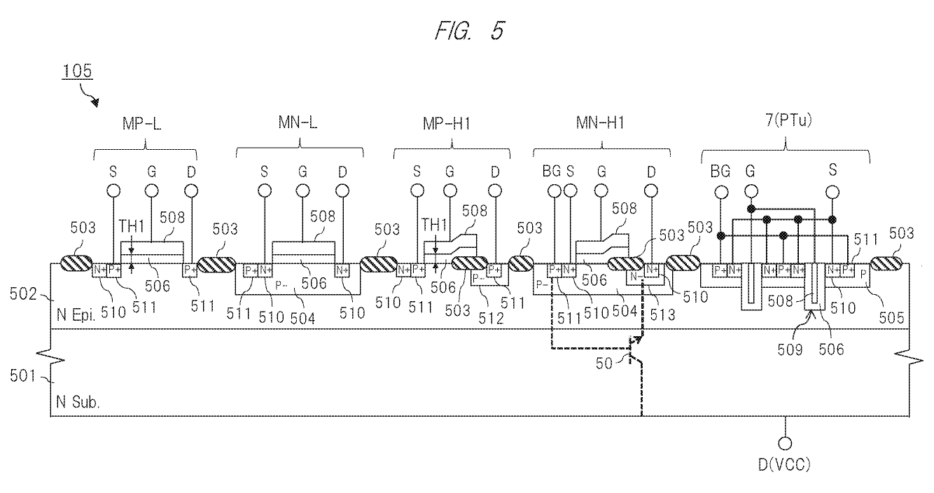

FIG. 5 is a cross-sectional view illustrating an example of a device structure in the semiconductor device 105 illustrated in FIG. 1. The structures of the pMOS transistor MP-H1 and the nMOS transistor MN-H1 of the high-voltage specification illustrated in FIG. 5 are different from those illustrated in FIG. 15. Specifically, the pMOS transistor MP-H1 and the nMOS transistor MN-H1 of the high-voltage specification include the thin gate oxide film 506 having the film thickness TH1 instead of the thick gate oxide film 507 having the film thickness TH2 illustrated in FIG. 15.

That is, the clamp element 16 is provided, so that the gate-source voltage VGSd and the gate-back gate voltage of the detection transistor 15 can be limited as illustrated in FIG. 2. Similarly, the clamp element 35 is provided, so that the gate-source voltage VGSc2 and the gate-back gate voltage of the control switch 34 can be limited. Therefore, the detection transistor 15 and the control switch 34 can be realized by the nMOS transistor MN-H1 having the thin gate oxide film 506. As a result, unlike the case of FIG. 15, the step of forming the gate oxide film 507 having the thick film thickness TH2 is not required in the manufacturing process, so that the manufacturing cost can be reduced.

### Application Example to Electronic Control System ECU

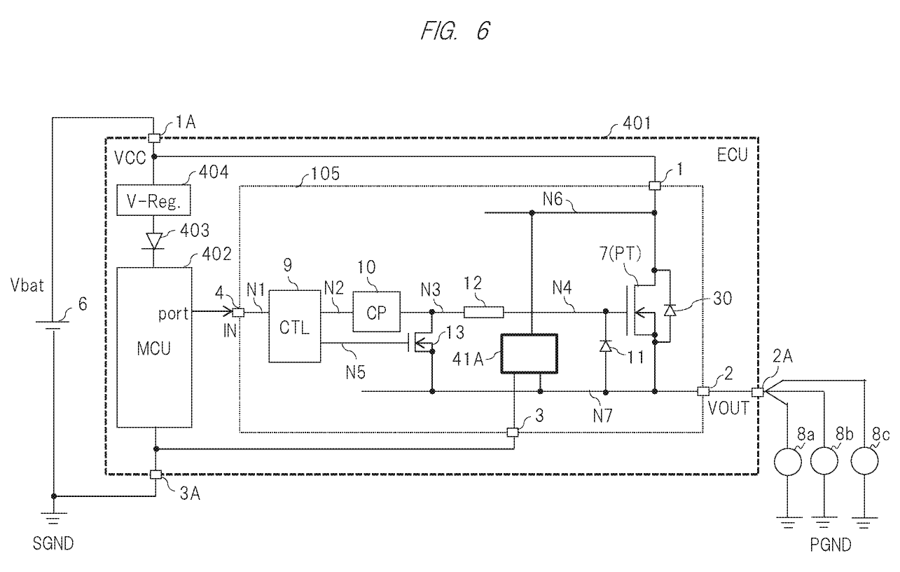

FIG. 6 is a circuit block diagram illustrating a configuration example of an electronic control system (ECU) 401 to which the semiconductor device 105 illustrated in FIG. 1 is applied. The electronic control system (ECU) 401 illustrated in FIG. 6 includes a power supply regulator 404 and a diode 403, and an ECU control device 402, here, a microcontroller unit (MCU), in addition to the semiconductor device 105 illustrated in FIG. 1. The electronic control system (ECU) 401 can include a wiring board or the like on which these components are mounted.

In addition, the electronic control system (ECU) 401 includes a power supply terminal 1A, a ground power supply terminal 3A, and a power output terminal 2A. A battery 6 is connected between the power supply terminal 1A and the ground power supply terminal 3A. The load is connected to the power output terminal 2A. In this example, the load is vehicle lamp loads 8a to 8c. The loads 8a to 8c have the other end to which the ground power supply voltage PGND is supplied.

The power supply terminal 1A receives a battery voltage Vbat. The power supply regulator 404 receives the power supply voltage VCC obtained at the power supply terminal 1A, and generates a low-voltage power supply voltage for the ECU control device 402. The generated power supply voltage is supplied to the ECU control device 402 via the diode 403. In addition, the ground power supply voltage SGND of the battery 6 is supplied to one end of the ECU control device 402 via the ground power supply terminal 3A. The diode 403 functions to protect the ECU control device 402, and prevents a reverse current from flowing through the ECU control device 402 when the battery 6 is reversely connected or in other cases.

The power supply voltage VCC from the power supply terminal 1A of the electronic control system (ECU) 401 is supplied to the power supply terminal 1 of the semiconductor device 105. The power output terminal 2 of the semiconductor device 105 is connected to the power output terminal 2A of the electronic control system (ECU) 401. In addition, the ground power supply voltage SGND is supplied to the ground power supply terminal 3 of the semiconductor device 105 via the ground power supply terminal 3A of the electronic control system (ECU) 401.

An output port of the ECU control device 402 is connected to the control input terminal 4 of the semiconductor device 105. The ECU control device 402 outputs the on/off control signal IN for instructing on/off of the power transistor (PT) 7 to the semiconductor device 105. The semiconductor device 105 controls power supply to the lamp loads 8a to 8c based on the on/off control signal IN from the control input terminal 4. Here, for example, when the counter electromotive voltage is generated at the power output terminal 2A the moment the power supply to the lamp loads 8a to 8c is stopped, the semiconductor device 105 performs the avalanche clamping operation.

Then, even when the on/off control signal IN becomes the “H” level during the period of the avalanche clamping operation, the semiconductor device 105 can maintain the avalanche clamping operation, that is, the off-state of the power transistor (PT) 7. As a result, the power transistor (PT) 7 can be appropriately protected within the safe operation area (SOA). Therefore, it is possible to increase the reliability of the electronic control system (ECU) 401.

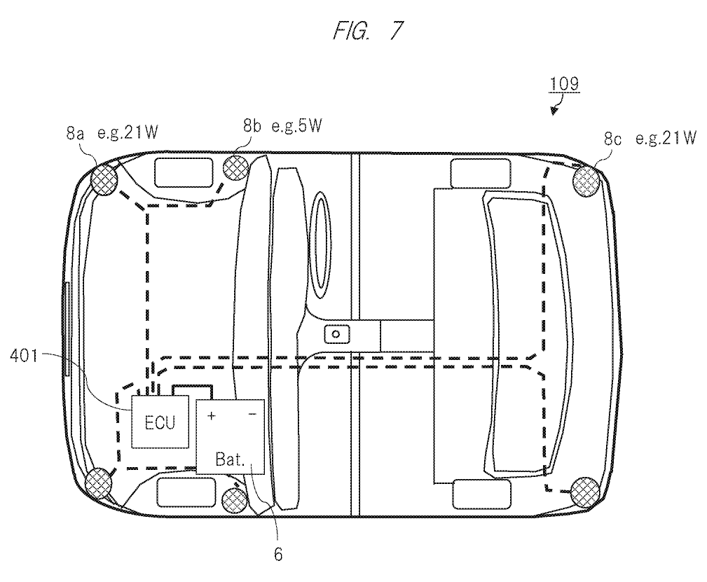

FIG. 7 is a schematic diagram illustrating a configuration example of a vehicle 109 on which the electronic control system (ECU) 401 illustrated in FIG. 6 is mounted. The vehicle 109 is, for example, an automobile. The vehicle 109 illustrated in FIG. 7 is mounted with the battery 6, the electronic control system 401, and the lamp loads 8a to 8c as illustrated in FIG. 6. For example, the rated powers of the lamp loads 8a, 8b, and 8c are 21 W, 5 W, 21 W, or the like, respectively.

The electronic control system 401 and the lamp loads 8a to 8c are connected by a wire harness. Here, more specifically, two sets of lamp loads 8a to 8c are provided for right turn and left turn. Accordingly, the electronic control system (ECU) 401 may be configured such that one ECU control device 402 controls two semiconductor devices 105. The ground power supply voltage PGND illustrated in FIG. 6 is connected to, for example, a housing of the vehicle 109.

### Main Effects of First Embodiment

As described above, the semiconductor device 105 according to the first embodiment includes the detection transistor 15 that detects the counter electromotive voltage from the load 8, the clamp element 16 that clamps the gate-source voltage VGSd, and the gate connection circuit 42 connected to the gate of the detection transistor 15. This makes it possible to realize the avalanche clamping operation without causing destruction of the output transistor, while forming the detection transistor 15 using the thin gate oxide film 506. As a result, the manufacturing cost can be reduced.

### Second Embodiment

### Circuit Configuration of Semiconductor Device

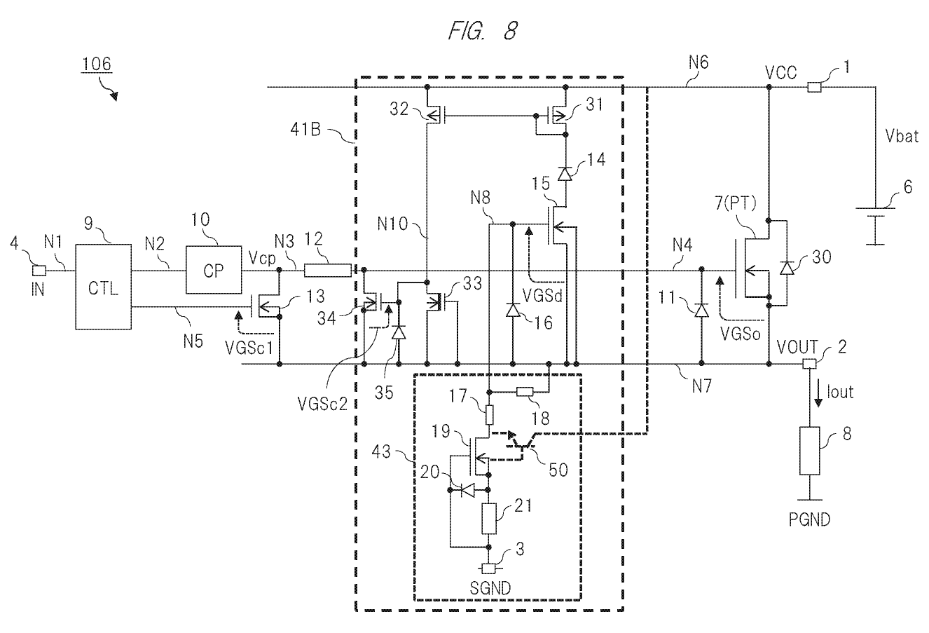

FIG. 8 is a circuit diagram illustrating a configuration example of a main part of a semiconductor device 106 according to a second embodiment. In the semiconductor device 106 illustrated in FIG. 8, the configuration of a protection circuit 41B, specifically, a gate connection circuit 43 is different from the configuration example illustrated in FIG. 1. In the gate connection circuit 43, more specifically, the nMOS transistor 19 includes the NPN parasitic bipolar transistor 50 having a vertical structure as described in FIG. 15. The parasitic bipolar transistor 50 operates using the drain of the nMOS transistor 19 as an emitter and the source and the back gate as bases as illustrated in FIG. 8. The collector of the parasitic bipolar transistor 50 is connected to the power supply node N6.

Here, for example, assume the case where the operation is performed during the period T3 illustrated in FIG. 2, that is, the negative voltage period on the premise that the parasitic bipolar transistor 50 is present in the configuration example illustrated in FIG. 1. In this case, a forward current flows through a body diode of the nMOS transistor 19 using the source and the back gate as the anode and the drain as the cathode. As a result, the parasitic bipolar transistor 50 can be turned on. Then, the drain voltage of the nMOS transistor 19 rises toward the power supply voltage VCC. As a result, since a current flowing through the clamp element 16 increases, the gate-source voltage VGSd of the detection transistor 15 may become excessively high.

To respond to this problem, in FIG. 8, a resistance element (third resistance element) 21 and a clamp element 20 are connected to the nMOS transistor 19. As in the case of FIG. 1, the ground power supply voltage SGND is applied to the gate of the nMOS transistor 19. However, unlike the case of FIG. 1, the ground power supply voltage SGND is applied to the source of the nMOS transistor 19 via the resistance element 21. The resistance element 21 can be made of, for example, polysilicon. In addition, the clamp element 20, specifically, the zener diode limits the gate-source voltage of the nMOS transistor 19 to a predetermined clamp voltage.

In such a configuration, when the output voltage VOUT becomes a negative voltage due to the counter electromotive voltage, a current flows sequentially from the ground power supply terminal 3 toward the power output node N7 via the resistance element 21, the body diode of the nMOS transistor 19, and the resistance elements 17 and 18. At this time, a voltage drop occurs in the resistance element 21. When this voltage drop exceeds the threshold voltage of the nMOS transistor 19, the nMOS transistor 19 is turned on. The drain-source voltage of the nMOS transistor drops due to turn-on. As a result, the parasitic bipolar transistor 50 can maintain the off-state with a smaller base-emitter voltage.

### Main Effects of Second Embodiment

As described above, the same effects as the various effects described in the first embodiment can also be obtained by using the semiconductor device 106 according to the second embodiment. Furthermore, when the counter electromotive voltage is generated at the power output terminal 2, the parasitic bipolar transistor 50 of the nMOS transistor 19 can be maintained in the off-state. As a result, it is possible to prevent a problem associated with turn-on of the parasitic bipolar transistor 50. Specifically, it is possible to prevent a situation in which a withstand voltage violation of the detection transistor 15 occurs due to an increase in the clamp voltage of the clamp element 16.

### Third Embodiment

### Circuit Configuration of Semiconductor Device

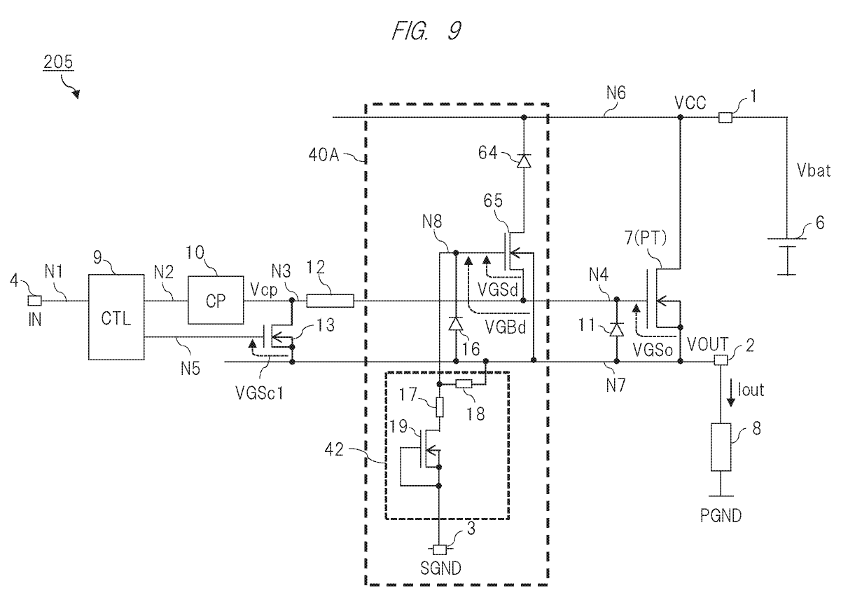

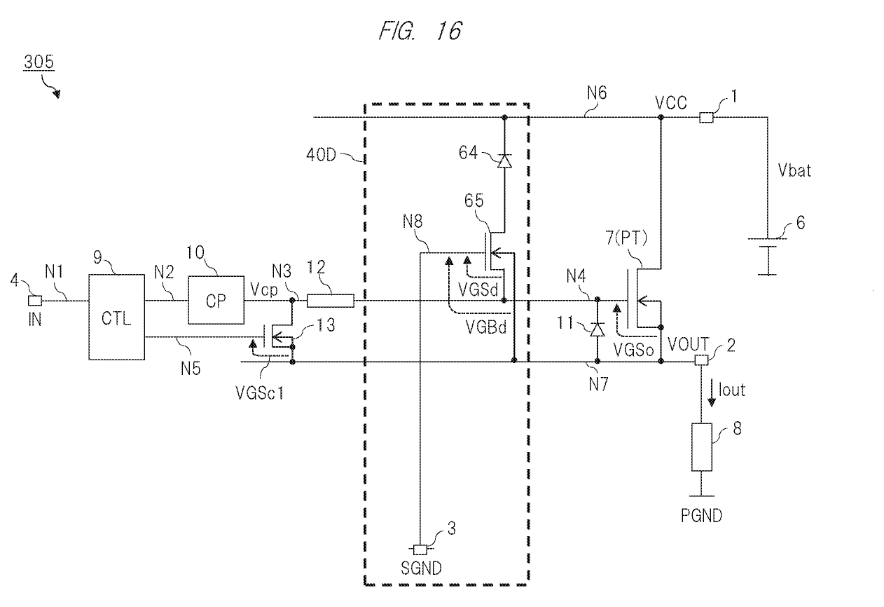

FIG. 9 is a circuit diagram illustrating a configuration example of a main part of a semiconductor device 205 according to a third embodiment. FIG. 16 is a circuit diagram illustrating a configuration example of a main part of a semiconductor device 305 that is a second comparative example with reference to FIG. 9. First, to facilitate understanding of the invention, FIG. 16 will be described prior to the description of FIG. 9. The semiconductor device 305 that is the second comparative example illustrated in FIG. 16 includes a dynamic clamp circuit 40D instead of the protection circuit 41A illustrated in FIG. 1. Other configurations are the same as those in FIG. 1, and thus detailed description is omitted.

Here, the protection circuit 41A illustrated in FIG. 1 is a circuit for preventing a problem when the semiconductor device 105 performs the avalanche clamping operation, that is, a problem when the on/off control signal IN becomes the “H” level during the negative voltage period as illustrated in FIG. 2. On the other hand, the dynamic clamp circuit 40D is a circuit for causing the semiconductor device 305 to perform a dynamic clamping operation different from the avalanche clamping operation.

The dynamic clamp circuit 40D includes a clamp element 64 and a detection transistor 65. As in the case of FIG. 1, the detection transistor 65 is inserted into the path between the power supply terminal 1, that is, the power supply node N6, and the power output terminal 2, that is, the power output node N7. The detection transistor 65 is configured to be turned on when the counter electromotive voltage is generated at the power output terminal 2 and then the source voltage changes in conjunction with the counter electromotive voltage. Specifically, the detection transistor 65 is constituted by an nMOS transistor having a gate to which the ground power supply voltage SGND is applied.

However, unlike the case of FIG. 1, the source of the detection transistor 65 is connected to the gate node N4 of the power transistor (PT) 7. The back gate of the detection transistor 65 is connected to the power output terminal 2, that is, the power output node N7, as in the case of FIG. 1. On the other hand, the clamp element (third clamp element) 64 is inserted into a path between the power supply node N6 and the drain of the detection transistor 65. The clamp element 64, specifically a zener diode, is provided to limit the counter electromotive voltage generated at the power output terminal 2 to a predetermined clamp voltage.

In the dynamic clamping operation, the counter electromotive voltage is clamped not by the body diode of the power transistor (PT) 7, but by the clamp voltage of the clamp element 64 and the gate-source voltage VGSo of the power transistor (PT) 7 in the weak on-state. The flyback energy associated with the counter electromotive voltage is consumed due to the on-resistance of the power transistor (PT) 7 in the weak on-state.

Here, the gate-source voltage VGSo of the power transistor (PT) 7 is determined by the gate resistance element 12 and the control switch (second control switch) 13. That is, the control switch 13 connects the gate node N4 of the power transistor (PT) 7 to the power output node N7 via the gate resistance element 12 when being controlled to be turned on in response to the transition of the on/off control signal IN to the off-level. In this state, when a current flows through the gate resistance element 12, a voltage drop occurs. The gate-source voltage VGSo is determined by this voltage drop.

As a specific example, assume that the power supply voltage VCC is 12 V and the clamp voltage of the clamp element 64, that is, a zener voltage Vz64 is 33.5 V. First, when the power transistor (PT) 7 is turned off, the counter electromotive voltage, that is, a negative voltage is generated at the power output terminal 2. At this time, the gate voltage of the power transistor (PT) 7 drops in conjunction with the drop in the output voltage VOUT due to the gate resistance element 12 and the control switch 13 in the on-state.

Here, when the gate voltage of the power transistor (PT) 7 drops by the zener voltage Vz64 of 33.5 V with reference to the power supply voltage VCC of 12 V, the gate voltage is clamped to -21.5 V by the clamp element 64 and the detection transistor 65 in the on-state. At this time, at the gate resistance element 12, for example, the voltage drop of about 1.5 V occurs due to the current flowing through the detection transistor 65. As a result, the output voltage VOUT is clamped to -23 V. The power transistor (PT) 7 is brought into the weak on-state since a gate-source voltage VGSo of about 1.5 V relative to a threshold voltage of about 1.0 V is applied, for example.

In the configuration and operation as described above, a high voltage can be applied between the gate and the back gate of the detection transistor 65 as in the case of the first embodiment. In response to this, a high voltage can also be applied between the gate and the source of the detection transistor 65. As an example, a gate-back gate voltage VGBd may be 23 V. In addition, the gate-source voltage VGSd may be 21.5 V. As a result, as in the case of the first embodiment, the step of forming a thick gate oxide film is required in the manufacturing process, so that the manufacturing cost may increase.

To respond to this problem, a dynamic clamp circuit 40A illustrated in FIG. 9 is provided. In addition to the clamp element 64 and the detection transistor 65 that are the same as those in FIG. 16, the dynamic clamp circuit 40A includes the clamp element 16 and the gate connection circuit 42 that are the same as those in FIG. 1. Briefly, the clamp element 16 limits the gate voltage of the detection transistor 65 to a predetermined clamp voltage, for example, 6 V or the like, based on the output voltage VOUT of the power output terminal 2. As a result, the gate-back gate voltage VGBd of the detection transistor 65 is clamped, and as a result, the gate-source voltage VGSd is also clamped.

The gate connection circuit 42 includes the resistance elements 17 and 18 and the nMOS transistor 19 that is a rectifier element. The nMOS transistor 19 applies the ground power supply voltage SGND to the gate of the detection transistor 65, and cuts off the current in the direction from the gate of the detection transistor 65 toward the ground power supply voltage SGND. Thus, when the power transistor (PT) 7 is in the on-state, the current path from the power output terminal 2 to the ground power supply terminal 3 via the clamp element 16 can be cut off.

The resistance element 18 connects the power output terminal 2 to the gate of the detection transistor 65. As a result, the detection transistor 65 can be maintained in the off-state during the period when the counter electromotive voltage is not generated. The resistance element 17 is connected in series to the nMOS transistor 19. The resistance element 17 limits the current flowing from the ground power supply terminal 3 to the clamp element 16 via the node N8 of the gate of the detection transistor 65 during the period when the counter electromotive voltage is generated. As a result, it is possible to suppress an increase in the clamp voltage at the clamp element 16, and thus an increase in the gate-back gate voltage VGBd and the gate-source voltage VGSd of the detection transistor 65.

By providing such a dynamic clamp circuit 40A, particularly the clamp element 16, the step of forming the thick gate oxide film is not required in the manufacturing process, as in the case of the first embodiment. That is, the semiconductor device 205 can be realized with the device structure as illustrated in FIG. 5. As a result, the manufacturing cost can be reduced. In addition, the semiconductor device 205 can be applied to, for example, the electronic control system (ECU) 401 as illustrated in FIG. 6, as in the case of the first embodiment. In this case, the power transistor (PT) 7 can be appropriately protected by performing the dynamic clamping operation for the counter electromotive voltage from the lamp loads 8a to 8c. As a result, it is possible to increase the reliability of the electronic control system (ECU) 401.

### Operation of Semiconductor Device

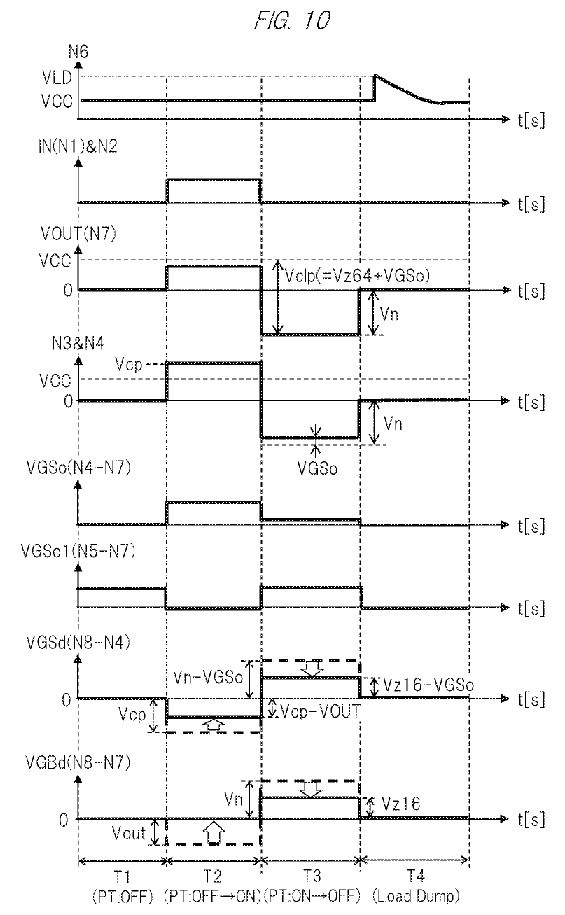

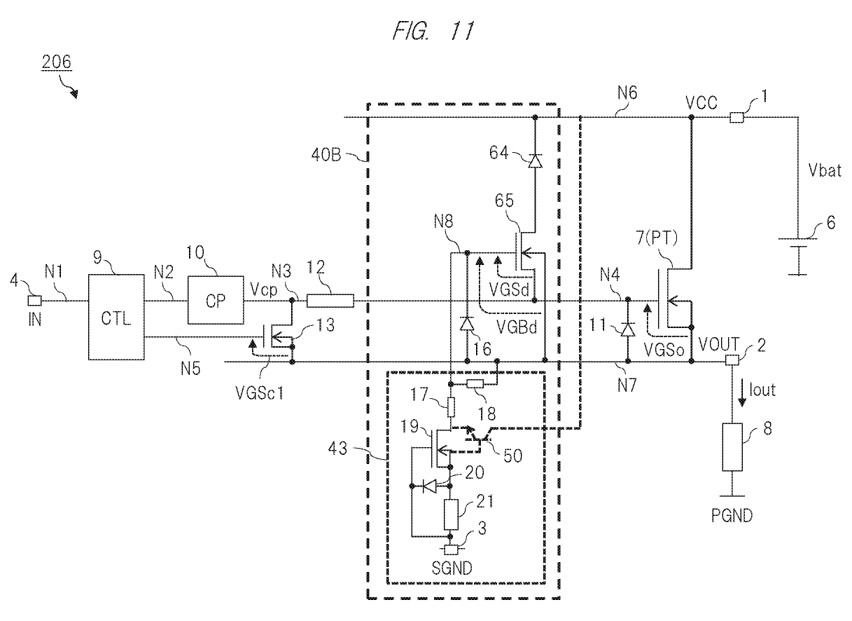

FIG. 10 is a timing chart illustrating an operation example of the semiconductor device 205 in FIG. 9. FIG. 10 illustrates the operation during the periods T1 to T4 as in the case of FIG. 2. In addition, in FIG. 10, the gate-source voltages VGSd and the gate-back gate voltage VGBd when the configuration example illustrated in FIG. 16 is used are also illustrated for comparison. Here, description will be made mainly focusing on a difference from the case of FIG. 2.

During the period T2, the output voltage VOUT becomes substantially at the same level as the power supply voltage VCC in response to the turn-on of the power transistor (PT) 7. At this time, the gate voltage of the detection transistor 65 becomes equal to the output voltage VOUT via the resistance element 18. The back gate voltage of the detection transistor 65 is equal to the output voltage VOUT. The boosted voltage Vcp is applied to the source of the detection transistor 65. As a result, the detection transistor 65 is brought into the off-state. In addition, the current from the power output terminal 2 to the ground power supply terminal 3, which can be generated during the period T2, is cut off by the nMOS transistor 19 functioning as the diode.

During the period T2, more specifically, the gate-back gate voltage VGBd of the detection transistor 65 becomes 0 V. The gate-source voltage VGSd of the detection transistor 65 is an off-voltage based on a difference voltage between the boosted voltage Vcp and the output voltage VOUT. The magnitude of the off-voltage is limited by the clamp voltage of the clamp element 11. On the other hand, when the configuration example illustrated in FIG. 16 is used, the magnitude of the gate-back gate voltage VGBd becomes the magnitude of the output voltage VOUT, which is substantially the magnitude of the power supply voltage VCC. In addition, the gate-source voltage VGSd becomes an off-voltage having the magnitude of the boosted voltage Vcp.

During the period T3, the counter electromotive voltage is generated in response to the turn-off of the power transistor (PT) 7, and then the output voltage VOUT becomes a negative voltage. Here, the dynamic clamp circuit 40A illustrated in FIG. 9 and the protection circuit 41A illustrated in FIG. 1 have different functions as described above. Therefore, unlike the case of FIG. 2, FIG. 10 illustrates an operation example when the on/off control signal IN does not transition to the on-level within the period T3.

When the output voltage VOUT becomes a negative voltage, the dynamic clamping operation using the dynamic clamp circuit 40A is performed. As a result, the ground power supply voltage SGND is applied to the gate of the detection transistor 65 via the nMOS transistor 19 and the resistance element 17. In addition, the source voltage of the detection transistor 65 changes in conjunction with the output voltage VOUT that is a negative voltage. As a result, the detection transistor 65 is brought into the on-state. The clamp element 64 is also brought into a conductive state when the negative voltage reaches a predetermined voltage.

The clamp voltage Vclp with reference to the output voltage VOUT is determined by the sum of the zener voltage Vz64 of the clamp element 64 and the gate-source voltage VGSo of the power transistor (PT) 7. As a result, the output voltage VOUT is clamped so as not to drop below the predetermined negative voltage Vn. The gate-source voltage VGSo of the power transistor (PT) 7 becomes an on-voltage having the magnitude of the weak on-state. In addition, the gate voltage of the gate node N4 of the power transistor (PT) 7 becomes a voltage higher than the negative voltage Vn generated at the power output node N7 by the gate-source voltage VGSo of the power transistor (PT) 7.

The gate-back gate voltage VGBd of the detection transistor 65 is limited by the zener voltage Vz16 of the clamp element 16. The gate-source voltage VGSd of the detection transistor 65 becomes an on-voltage based on a difference voltage between the zener voltage Vz16 and the gate-source voltage VGSo of the power transistor (PT) 7. On the other hand, when the configuration example illustrated in FIG. 16 is used, the magnitude of the gate-back gate voltage VGBd is the magnitude of the negative voltage Vn. In addition, the gate-source voltage VGSd is an on-voltage based on a difference voltage between the negative voltage Vn and the gate-source voltage VGSo of the power transistor (PT) 7.

During the period T3, a current flows from the ground power supply terminal 3 to the power output terminal 2 via the clamp element 16. The resistance element 17 limits the current flowing through the clamp element 16 at this time. In addition, in the dynamic clamping operation, the flyback energy associated with the counter electromotive voltage is released due to the on-resistance of the power transistor (PT). When the flyback energy is completely released, the output voltage VOUT becomes the ground power supply voltage PGND.

During the period T4, the load dump occurs at the power node N6. As in the case of FIG. 2, the detection transistor 65 is configured to be capable of maintaining the off-state against the load dump. As a result, the dynamic clamping operation is not performed against the load dump.

### Circuit Configuration of Semiconductor Device Modification

FIG. 11 is a circuit diagram illustrating a configuration example of a semiconductor device 206 according to the third embodiment, obtained by modifying FIG. 9. The semiconductor device 206 illustrated in FIG. 11 includes a gate connection circuit 43 different from that in FIG. 9. As described in the second embodiment, more specifically, the nMOS transistor 19 in the gate connection circuit 42 illustrated in FIG. 9, includes the parasitic bipolar transistor 50. In this case, when the parasitic bipolar transistor 50 is turned on during the period T3, the drain voltage of the nMOS transistor 19 increases, and the current flowing through the clamp element 16 may increase.

To prevent such a problem, in the gate connection circuit 43 illustrated in FIG. 11, the resistance element 21 and the clamp element 20 are connected to the nMOS transistor 19 as in the case of FIG. 8. The ground power supply voltage SGND is applied to the source of the nMOS transistor 19 via the resistance element 21. The clamp element 20 limits the gate-source voltage of the nMOS transistor 19 to a predetermined clamp voltage.

### Main Effects of Third Embodiment

As described above, the same effects as the various effects described in the first and second embodiments can be obtained by using the semiconductor devices 205 and 206 according to the third embodiment. That is, it is possible to realize the dynamic clamping operation, while forming the detection transistor 65 using the thin gate oxide film 506. As a result, the manufacturing cost can be reduced. In addition, it is possible to prevent a problem associated with the turn-on of the parasitic bipolar transistor 50.

### Fourth Embodiment

### Structure of Semiconductor Device

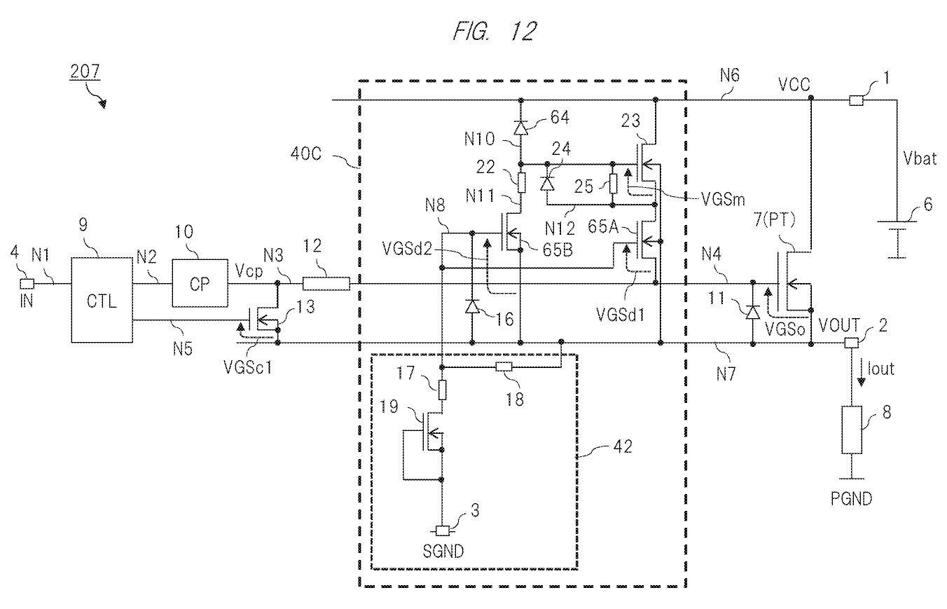

FIG. 12 is a circuit diagram illustrating a configuration example of a main part of a semiconductor device 207 according to a fourth embodiment. The semiconductor device 207 illustrated in FIG. 12 includes a dynamic clamp circuit 40C different from that in FIG. 9. The dynamic clamp circuit 40C includes two detection transistors 65A and 65B, a resistance element 22, an nMOS transistor 23 for clamping, a clamp element 24, and a resistance element 25, in addition to the clamp elements 16 and 64 and the gate connection circuit 42 having the same roles as those in the case of FIG. 9.

The gates of the two detection transistors 65A and 65B are commonly connected, and the back gates thereof are both connected to the power output terminal 2. The clamp element (first clamp element) 16 limits the gate voltages of the detection transistors 65A and 65B to a predetermined clamp voltage with reference to the output voltage VOUT of the power output terminal 2. In the detection transistor (first detection transistor) 65B, the source is connected to the power output terminal 2, and the drain is connected to the power supply terminal 1 via the clamp element (third clamp element) 64. However, in this example, the resistance element 22 is connected between the drain of the detection transistor 65B and the clamp element 64.

In the detection transistor (second detection transistor) 65A, the source is connected to the gate node N4 of the power transistor (PT) 7 and the drain is connected to the power supply terminal 1 via the nMOS transistor 23 for clamping. The clamp element (fourth clamp element) 24, specifically the zener diode, and the resistance element (fourth resistance element) 25 are connected in parallel between the gate and the source of the nMOS transistor 23 for clamping. In addition, the gate of the nMOS transistor 23 for clamping is connected to the power supply terminal 1 via the clamp element 64. The back gate of the nMOS transistor 23 for clamping is connected to the power output terminal 2.

Here, both the detection transistors 65A and 65B have the role in detecting a negative voltage generated at the power output terminal 2, and are brought into the on-state when the negative voltage is detected. When the negative voltage reaches a predetermined value, the clamp element 64 is brought into a conductive state via the detection transistor 65B in the on-state. As a result, a voltage obtained when the power supply voltage VCC drops by the zener voltage Vz64 of the clamp element 64 is applied to the gate of the nMOS transistor 23 for clamping. The nMOS transistor 23 for clamping receives such a gate voltage, and clamps the source voltage of the node N12 with its own gate-source voltage VGSm.

As a result, the gate voltage of the power transistor (PT) 7 is also clamped from the node N12 via the detection transistor 65A in the on-state. The clamp voltage at this time is determined by the sum of the zener voltage Vz64 of the clamp element 64 and the gate-source voltage VGSm of the nMOS transistor 23 for clamping. Accordingly, the output voltage VOUT of the power output terminal 2 is also clamped by the dynamic clamping operation. The clamp voltage at this time is determined by the sum of the zener voltage Vz64, the gate-source voltage VGSm, and the gate-source voltage VGSo of the power transistor (PT) 7.

Note that the clamp element 24 limits the gate-source voltage VGSm of the nMOS transistor 23 for clamping to a clamp voltage of 6 V or the like, for example. The resistance element 25 maintains the nMOS transistor 23 in the off-state during the non-conduction period of the clamp element 64. The resistance element 22 is provided to limit the current flowing through the clamp element 64, that is, to suppress a variation in the clamp voltage. However, the resistance element 22 may be omitted. In addition, the resistance element 22 may be, for example, a depletion-type MOS transistor whose gate and source are short-circuited to reduce the circuit area.

### Operation of Semiconductor Device

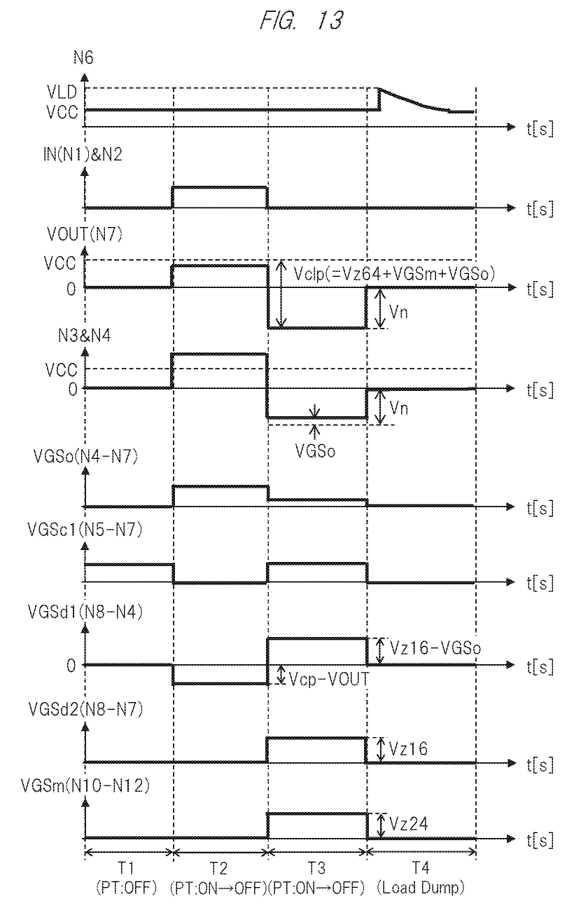

FIG. 13 is a timing chart illustrating an operation example of the semiconductor device 207 in FIG. 12. FIG. 12 illustrates the operation during the periods T1 to T4 as in the case of FIG. 10. Here, description will be made mainly focusing on a difference from the case of FIG. 10.

During the period T1, the output voltage VOUT is the ground power supply voltage PGND, that is, 0 V in response to the off-state of the power transistor (PT) 7. In this state, a gate-source voltage VGSd2 of the detection transistor 65B is 0 V due to the resistance element 18. A gate-source voltage VGSd1 of the detection transistor 65A is 0 V due to the resistance element 18 and the control switch 13 in the on-state. In addition, the gate-source voltage VGSm of the nMOS transistor 23 for clamping is 0 V due to the resistance element 25.

During the period T2, the output voltage VOUT becomes substantially at the same level as the power supply voltage VCC in response to the turn-on of the power transistor (PT) 7. At this time, the gate-source voltage VGSd2 of the detection transistor 65B becomes 0 V due to the resistance element 18. On the other hand, the boosted voltage Vcp is applied to the source of the detection transistor 65A. As a result, the gate-source voltage VGSd1 of the detection transistor 65A is an off-voltage based on the difference voltage between the boosted voltage Vcp and the output voltage VOUT, that is, the substantial power supply voltage VCC. In addition, the gate-source voltage VGSm of the nMOS transistor 23 for clamping is 0 V due to the resistance element 25.

During the period T3, the counter electromotive voltage is generated in response to the turn-off of the power transistor (PT) 7, and then the output voltage VOUT becomes a negative voltage. As a result, the dynamic clamping operation using the dynamic clamp circuit 40C is performed. The ground power supply voltage SGND is applied to the gates of the detection transistors 65A and 65B via the nMOS transistor 19 and the resistance element 17. In addition, the source voltage of the detection transistor 65A changes in conjunction with the output voltage VOUT that is a negative voltage. As a result, both the detection transistors 65A and 65B are brought into the on-state. The clamp element 64 is also brought into a conductive state when the negative voltage reaches a predetermined voltage.

The clamp voltage Vclp with reference to the output voltage VOUT is determined by the sum of the zener voltage Vz64 of the clamp element 64, the gate-source voltage VGSm of the nMOS transistor 23 for clamping, and the gate-source voltage VGSo of the power transistor (PT) 7. As a result, the output voltage VOUT is clamped so as not to drop below the predetermined negative voltage Vn.

The gate-source voltage VGSd2 of the detection transistor 65B becomes an on-voltage limited by the zener voltage Vz16 of the clamp element 16. The gate-back gate voltages of the detection transistors 65A and 65B are also limited by the zener voltage Vz16. On the other hand, the gate-source voltage VGSd1 of the detection transistor 65A becomes an on-voltage based on the difference voltage between the zener voltage Vz16 and the gate-source voltage VGSo of the power transistor (PT) 7. In addition, the gate-source voltage VGSm of the nMOS transistor 23 for clamping becomes an on-voltage limited by the zener voltage Vz24 of the clamp element 24.

### Semiconductor Device Modification

The dynamic clamp circuit 40C illustrated in FIG. 12 includes the gate connection circuit 42. However, instead of the gate connection circuit 42, the gate connection circuit 43 as illustrated in FIG. 11 may be provided. As a result, in the nMOS transistor 19, it is possible to prevent a problem associated with the turn-on of the parasitic bipolar transistor 50.

### Main Effects of Fourth Embodiment

As described above, the same effects as the various effects described in the third embodiment can also be obtained by using the semiconductor device 207 according to the fourth embodiment. In addition, the same detection transistor as in the third embodiment, that is, the detection transistor 65B which is the same detection transistor as in the first embodiment and whose gate and source are connected to the power output terminal 2 can be used together to realize the dynamic clamping operation. However, from the viewpoint of a circuit area and the like, the third embodiment is more desirable.

### Other Embodiments

In the first to fourth embodiments described above, a semiconductor device that supplies the power supply voltage VCC to the load 8 having one end to which the ground power supply voltage PGND is supplied, that is, a high-side semiconductor device, has been described as an example. However, the methods of the first to fourth embodiments can also be applied to a semiconductor device that supplies the ground power supply voltage PGND to the load 8 having one end to which the power supply voltage VCC is supplied, that is, a low-side semiconductor device.

In this case, the counter electromotive voltage generated at the power output terminal 2 is not a negative voltage but a positive voltage. To respond to this, for example, the detection transistor 15 can be constituted by a pMOS transistor in FIG. 1. In addition, the nMOS transistor 19 in the gate connection circuit 42 can be replaced with a pMOS transistor in which the power supply voltage VCC is applied to the gate and the source.

Although the invention made by the present inventor has been specifically described based on the embodiments, the present invention is not limited to the above-described embodiments, and various modifications can be made without departing from the gist of the present invention. For example, the above-described embodiments explain about the details to describe the present invention in an easy-to-understand manner, and are not necessarily limited to those having all the described configurations. In addition, a part of the configuration of a certain embodiment can be replaced with the configuration of another embodiment, and the configuration of another embodiment can be added to the configuration of a certain embodiment. Furthermore, another configuration can be added to, deleted from, and replaced with a part of the configuration of each embodiment.

What is claimed is:

1. A semiconductor device comprising:
an output transistor connected between a first power supply terminal to which a first power supply voltage is supplied and a power output terminal, and, when controlled to be turned on, configured to supply power to a load having one end to which a second power supply voltage is supplied, via the power output terminal;
a detection transistor inserted into a path between the first power supply terminal and the power output terminal, and configured to be turned on when a counter electromotive voltage is generated at the power output terminal and then a source voltage changes in conjunction with the counter electromotive voltage;
a first clamp element configured to limit a gate voltage of the detection transistor to a predetermined clamp voltage with reference to a voltage of the power output terminal; and
a gate connection circuit connected to a gate of the detection transistor,
wherein the gate connection circuit comprises:
a first resistance element configured to connect the power output terminal to the gate of the detection transistor; and
a rectifier element configured to apply the second power supply voltage to a gate of the detection transistor and cut off a current in a direction from the gate of the detection transistor toward the second power supply voltage.

2. The semiconductor device according to claim 1, further comprising:
a second resistance element connected in series to the rectifier element and configured to limit a current flowing from the second power supply voltage to the first clamp element via the gate of the detection transistor.

3. The semiconductor device according to claim 1,
wherein the rectifier element comprises a transistor whose gate and source are short-circuited.

4. The semiconductor device according to claim 1,
wherein the rectifier element comprises a transistor and a third resistance element, and
wherein the second power supply voltage is applied to a gate of the transistor, and the second power supply voltage is applied to a source of the transistor via the third resistance element.

5. The semiconductor device according to claim 1, further comprising:
a first control switch configured to control the output transistor to be turned off during a period when the detection transistor is on,
wherein a source of the detection transistor is connected to the power output terminal.

6. The semiconductor device according to claim 5, further comprising:
a zener diode inserted into a path between the first power supply terminal and a drain of the detection transistor,
wherein a zener voltage of the zener diode is lower than a clamp voltage of a body diode of the output transistor.

7. The semiconductor device according to claim 5, further comprising:
a current mirror circuit configured to copy a current flowing through the detection transistor; and
a voltage conversion element configured to convert a current flowing through a copy destination of the current mirror circuit into a voltage,
wherein the first control switch is controlled to be turned on and off by the voltage converted by the voltage conversion element, and, when controlled to be turned on, short-circuits the gate and the source of the output transistor.

8. The semiconductor device according to claim 7, further comprising:
a second clamp element,
wherein the first control switch comprises a MOS transistor whose source and gate are connected to the power output terminal and the voltage conversion element, respectively, and
wherein the second clamp element limits a gate-source voltage of the MOS transistor to a predetermined clamp voltage.

9. The semiconductor device according to claim 1, further comprising:
a third clamp element inserted into a path between the first power supply terminal and the drain of the detection transistor, and configured to limit the counter electromotive voltage to a predetermined clamp voltage;
a gate resistance element; and
a second control switch configured to connect the gate of the output transistor to the power output terminal via the gate resistance element when controlled to be turned on,
wherein a source of the detection transistor is connected to a gate of the output transistor.

10. The semiconductor device according to claim 9,
wherein a back gate of the detection transistor is connected to the power output terminal.

11. The semiconductor device according to claim 9, further comprising:
a transistor for clamping; and
a fourth clamp element and a fourth resistance element connected in parallel between a gate and a source of the transistor for clamping,
wherein the detection transistor comprises a first detection transistor and a second detection transistor whose gates are commonly connected,
wherein a source of the first detection transistor is connected to the power output terminal, and a drain of the first detection transistor is connected to the first power supply terminal via the third clamp element,
wherein a source of the second detection transistor is connected to a gate of the output transistor, and a drain of the second detection transistor is connected to the first power supply terminal via the transistor for clamping, and
wherein a gate of the transistor for clamping is connected to the first power supply terminal via the third clamp element.

12. An electronic control system comprising:
a first power supply terminal to which a first power supply voltage is supplied;
a power output terminal connected to a load;
a semiconductor device configured to supply power to the load; and
a control device configured to control the semiconductor device,
wherein a second power supply voltage is supplied to one end of the load,
wherein the semiconductor device comprises
an output transistor connected between the first power supply terminal and the power output terminal and, when controlled to be turned on, configured to supply power to the load via the power output terminal;
a detection transistor inserted into a path between the first power supply terminal and the power output terminal, and configured to be turned on when a counter electromotive voltage is generated at the power output terminal, and then a source voltage changes in conjunction with the counter electromotive voltage;
a first clamp element configured to limit a gate voltage of the detection transistor to a predetermined clamp voltage with reference to a voltage of the power output terminal; and
a gate connection circuit connected to a gate of the detection transistor,
wherein the gate connection circuit comprises
a first resistance element configured to connect the power output terminal to the gate of the detection transistor; and
a rectifier element configured to apply the second power supply voltage to the gate of the detection transistor and cut off a current in a direction from the gate of the detection transistor toward the second power supply voltage, and
wherein the control device outputs an on/off control signal for instructing turn on/off of the output transistor to the semiconductor device.

13. The electronic control system according to claim 12,
wherein the semiconductor device further comprises a second resistance element connected in series to the rectifier element and configured to limit a current flowing from the second power supply voltage to the first clamp element via the gate of the detection transistor.

14. The electronic control system according to claim 12,
wherein the rectifier element comprises a transistor whose gate and source are short-circuited.

15. The electronic control system according to claim 12,
wherein the rectifier element comprises a transistor and a third resistance element, and
wherein the second power supply voltage is applied to a gate of the transistor, and the second power supply voltage is applied to a source of the transistor via the third resistance element.
